(19) United States
(12) Patent Application Publication
(10) Pub. No.: US 2026/0279412 A1
(43) Pub. Date: Sep. 17, 2026

(54) SEMICONDUCTOR STORAGE DEVICE AND MANUFACTURING METHOD THEREOF

(71) Applicant: Kioxia Corporation, Tokyo (JP)

(72) Inventors: Masaki NOGUCHI, Yokkaichi (JP); Kensei TAKAHASHI, Kuwana (JP); Saori MATSUSHITA, Yokkaichi (JP)

(73) Assignee: Kioxia Corporation, Tokyo (JP)

(21) Appl. No.: 19/316,472

(22) Filed: Sep. 2, 2025

(30) Foreign Application Priority Data
Mar. 17, 2025 (JP) 2025-042384

(51) Int. Cl. G11C 5/06; H01L 23/00; H10B 43/10; H10B 43/27; H10B 43/35; H10D 64/01; H10D 64/66; H10D 80/30

(52) U.S. Cl. CPC G11C 5/063; H10B 43/10; H10B 43/27; H10B 43/35; H10D 64/037; H10D 64/665; H10D 80/30; H10W 90/792

(57) ABSTRACT

A semiconductor storage device according to the present embodiment includes a stack of a plurality of electrode films and a plurality of first insulation films stacked alternately one layer at a time in a first direction. A columnar body includes a semiconductor layer provided to penetrate through the stack in the first direction. A second insulation film is provided between the columnar body and each of the electrode films. A conductive film is provided between each of the electrode films and the second insulation film. The conductive film contains molybdenum (Mo) containing a first material whose concentration is higher than an oxygen concentration.

### CROSS REFERENCE TO RELATED APPLICATIONS

This application is based upon and claims the benefit of priority from the prior Japanese Patent Application No. 2025-042384, filed on Mar. 17, 2025, the entire contents of which are incorporated herein by reference.

### FIELD

The embodiments of the present invention relate to a semiconductor storage device and a manufacturing method thereof.

### BACKGROUND

There is a case where a semiconductor storage device such as a NAND flash memory includes a three-dimensional memory cell array in which a plurality of memory cells are arranged three-dimensionally. In such a memory cell array, a nucleation layer may be used as an underlayer in order to form word lines of a stack of the memory cell array.

However, when a thin nucleation layer contains a large amount of oxygen, it is difficult to form the nucleation layer as a continuous layer, and the nucleation layer is broken. Such formation of the nucleation layer damages memory cells, and adversely affects growth of word lines. Further, when the nucleation layer contains a large amount of oxygen, the erase saturation characteristics and high temperature data retention characteristics (HTDR characteristics) of memory cells deteriorate.

### BRIEF DESCRIPTION OF THE DRAWINGS

FIG. 1 is a cross-sectional view illustrating a configuration example of a semiconductor storage device according to an embodiment of the present invention;

FIG. 2 is a plan view illustrating a stack;

FIG. 3 is a cross-sectional view of an example of a memory cell having a three-dimensional configuration;

FIG. 4 is a cross-sectional view of an example of the memory cell having a three-dimensional configuration;

FIG. 5 is a cross-sectional view for explaining a portion of the memory cell in FIG. 3 in more detail;

FIG. 6 is a cross-sectional view illustrating an example of a manufacturing method of the semiconductor storage device according to the embodiment;

FIG. 7 is a cross-sectional view illustrating an example of the manufacturing method of the semiconductor storage device in continuation from FIG. 6;

FIG. 8 is a cross-sectional view illustrating an example of the manufacturing method of the semiconductor storage device in continuation from FIG. 7;

FIG. 9 is a cross-sectional view illustrating an example of the manufacturing method of the semiconductor storage device in continuation from FIG. 8;

FIG. 10 is a cross-sectional view illustrating an example of the manufacturing method of the semiconductor storage device in continuation from FIG. 9;

FIG. 11 is a cross-sectional view illustrating an example of the manufacturing method of the semiconductor storage device in continuation from FIG. 10;

FIG. 12 is a conceptual diagram illustrating a process of depositing an electrode film on a broken nucleation film; and

FIG. 13 is a conceptual diagram illustrating a process of depositing an electrode film on a nucleation film according to the present embodiment.

### DETAILED DESCRIPTION

In general, according to the embodiment, a semiconductor storage device includes a stack of a plurality of electrode films and a plurality of first insulation films stacked alternately one layer at a time in a first direction. A columnar body includes a semiconductor layer provided to penetrate through the stack in the first direction. A second insulation film is provided between the columnar body and each of the electrode films. A conductive film is provided between each of the electrode films and the second insulation film. The conductive film contains molybdenum (Mo) containing a first material whose concentration is higher than an oxygen concentration.

Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

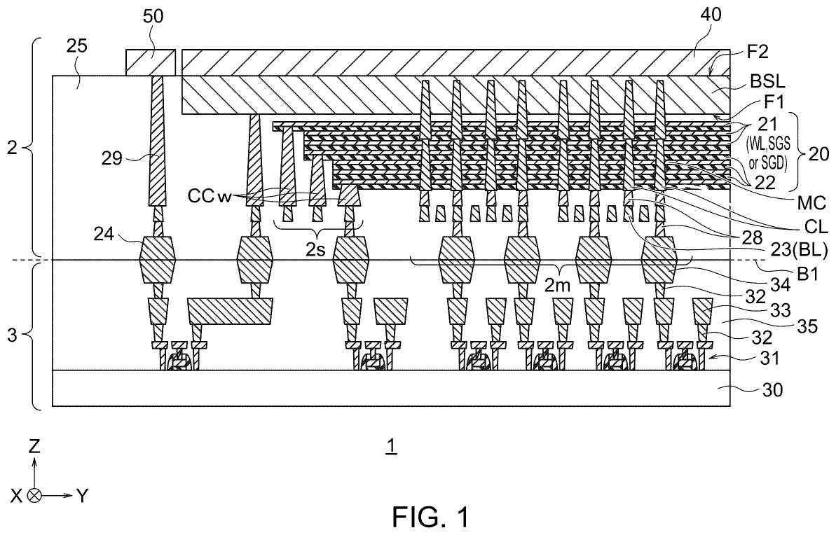

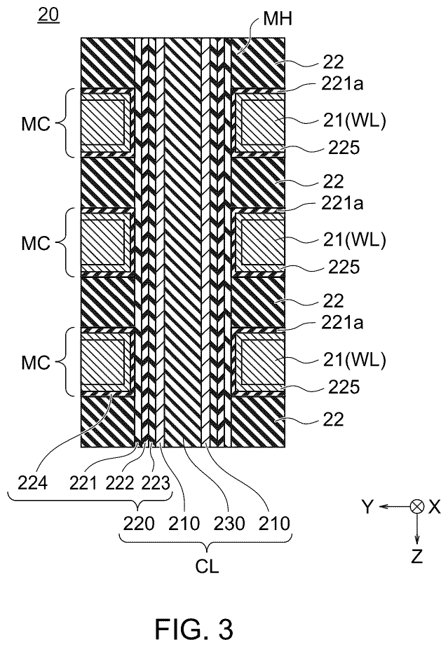

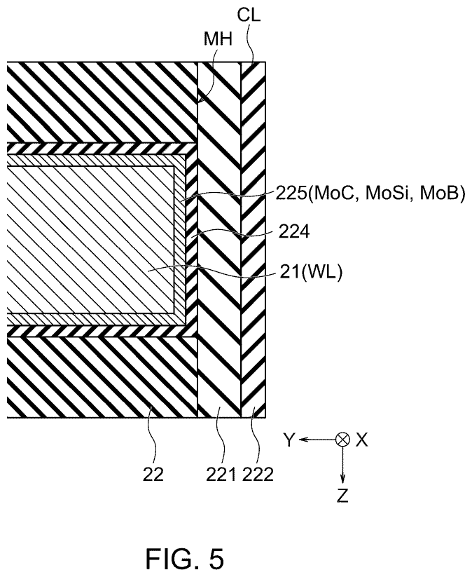

FIG. 1 is a cross-sectional view illustrating a configuration example of a semiconductor storage device 1 according to the present embodiment. In the following descriptions, the stacking direction of a stack 20 is defined as a Z direction. One direction that crosses the Z direction, for example, at right angles is defined as a Y direction. One direction that crosses the Z direction and the Y direction, for example, at right angles is defined as an X direction. FIG. 1 illustrates the semiconductor storage device 1 assuming that a +Z direction is an upward direction. In the cross-sectional views of FIG. 3 and FIG. 5 and the subsequent drawings, there is a case where an array chip is illustrated assuming that a −Z direction is the upward direction. In the present specification, ±Z directions are examples of a first direction.

The semiconductor storage device 1 includes an array chip 2 having a memory cell array and a CMOS (Complementary Metal Oxide Semiconductor) chip 3 having a CMOS circuit. The array chip 2 and the CMOS chip 3 are bonded together at a bonding surface B1 and are electrically connected to each other via wires joined at the bonding surface B1. FIG. 1 illustrates a state where the array chip 2 is provided on the CMOS chip 3.

The CMOS chip 3 includes a substrate 30, a transistor 31, a via 32, wires 33 and 34, and an interlayer dielectric film 35.

For example, the substrate 30 is a semiconductor substrate such as a silicon substrate. The transistor 31 is an NMOSFET (MOS Field Effect Transistor) or a PMOSFET provided on the substrate 30. The transistor 31 constitutes a CMOS circuit controlling a memory cell array 2m of the array chip 2, for example. A plurality of transistors 31 configure a logic circuit such as a sense amplifier, a row decoder, and a columnar decoder. Semiconductor elements other than the transistors 31, for example, a resistor element and a capacitor element may be formed on the substrate 30.

The via 32 electrically connects the transistor 31 and the wire 33 to each other or the wire 33 and the wire 34 to each other. The wires 33 and 34 constitute a multilayer wiring structure in the interlayer dielectric film 35. The wire 34 is embedded in the interlayer dielectric film 35 and is exposed in a surface of the interlayer dielectric film 35 to be substantially flush therewith. The wires 33 and 34 are electrically connected to the transistor 31 or the like. A metal such as copper or tungsten is used for the via 32 and the wires 33 and 34. The interlayer dielectric film 35 covers and protects the transistor 31, the via 32, and the wires 33 and 34. An insulation film, for example, a silicon oxide film is used as the interlayer dielectric film 35.

The array chip 2 includes the stack 20, a columnar body CL, a source layer BSL, a metal layer 40, a contact plug CCw, a contact plug 29, a bonding pad 50, wires 23 and 24, a via 28, and an interlayer dielectric film 25.

The stack 20 is provided above the transistor 31 and located in the +Z direction with respect to the substrate 30. The stack 20 is configured by a plurality of electrode films 21 and a plurality of insulation films 22 alternately stacked along the Z direction one layer at a time. The stack 20 constitutes a memory cell array together with the columnar body CL. A conductive metal, for example, molybdenum is used for the electrode films 21. A silicon oxide film is used as the insulation film 22, for example. The insulation films 22 each insulate the electrode films 21 from each other. That is, the electrode films 21 are stacked while being insulated from each other. The number of each of the stacked electrode films 21 and the stacked insulation films 22 may be any number. The insulation film 22 may be a porous insulation film or an air gap, for example.

One electrode film 21 or plural electrode films 21 at upper and lower ends in the Z direction of the stack 20 serve as a source-side selection gate SGS and a drain-side selection gate SGD, respectively. The electrode films 21 between the source-side selection gate SGS and the drain-side selection gate SGD each serve as a word line WL. The word line WL serves as a gate electrode of a memory cell MC. The source-side selection gate SGS is a gate electrode of a source-side selection transistor. The drain-side selection gate SGD is a gate electrode of a drain-side selection transistor. The source-side selection gate SGS is provided in an upper region of the stack 20. The drain-side selection gate SGD is provided in a lower region of the stack 20. The upper region means a region of the stack 20 farther from the CMOS chip 3 (closer to the metal layer 40), and the lower region means a region of stack 20 closer to the CMOS chip 3.

The semiconductor storage device 1 includes memory cells MC connected in series between the source-side selection transistor and the drain-side selection transistor. The configuration in which the source-side selection transistor, the memory cells MC, and the drain-side selection transistor are connected in series is called “memory string” or “NAND string”. The memory string is connected to a bit line BL, for example, via the via 28. The bit line BL is the wire 23 provided below the stack 20 and extending in the X direction. Therefore, in the following descriptions, the bit line BL is also described as “bit line 23”.

The stack 20 includes the columnar bodies CL provided therein. Each columnar body CL extends in the stack 20 to penetrate through the stack 20 in the stacking direction (the Z direction) of the stack 20 from the via 28 connected to the bit line 23 to the source layer BSL. The internal structure of the columnar body CL will be described later. In FIG. 1, a case is illustrated in which the columnar bodies CL are formed in two stages in the Z direction. However, the columnar bodies CL may be formed in three or more stages.

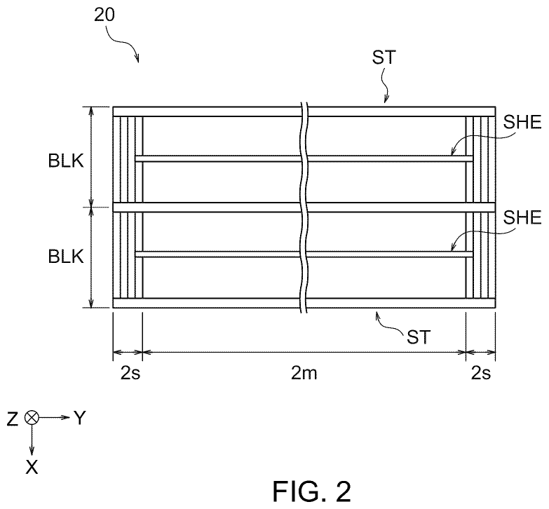

Although not illustrated in FIG. 1, a plurality of slits ST (see FIG. 2) are provided in the stack 20. The slits ST extend in the Y direction and penetrate through the stack 20 in the stacking direction (the Z direction) of the stack 20. Each slit ST is filled with an insulation film such as a silicon oxide film, and the insulation film is formed in a plate shape. The slits ST electrically divide the electrode films 21 of the stack 20. Alternatively, the inner wall of each slit ST may be covered with an insulation film such as a silicon oxide film, and further a conductive material may be embedded inside the insulation film. In this case, the conductive material can also serve as a source wire reaching the source layer BSL.

The source layer BSL is provided on the stack 20. The source layer BSL is provided to correspond to the stack 20. The stack 20 (the memory cell array 2m) is provided on the surface F1 side of the source layer BSL, and the metal layer 40 is provided on the opposite surface F2 side. The source layer BSL is connected to one ends of the columnar bodies CL in common to supply a common source voltage to the columnar bodies CL belonging to the same memory cell array 2m. That is, the source layer BSL serves as a common source electrode of the memory cell array 2m. A conductive material such as doped polysilicon is used for the source layer BSL. A metal material that is lower in resistance than the source layer BSL, for example, copper, aluminum, or tungsten is used for the metal layer 40.

Meanwhile, the bonding pad 50 is provided above the surface F2 of the source layer BSL in a region where the source layer BSL is not provided. The bonding pad 50 is connected to a metal wire (not illustrated) or the like and receives power supply or a signal from outside of the semiconductor storage device 1. The bonding pad 50 is provided to be connected to one end in the Z direction of the contact plug 29. The bonding pad 50 is connected to the transistor 31 of the CMOS chip 3 via the contact plug 29, the wire 24, and the wire 34. External power supplied from the bonding pad 50 is supplied to the transistor 31. Alternatively, a signal is supplied to the transistor 31 via the bonding pad 50.

The contact plug CCw is provided in the peripheral region of the stack 20 and extends in the Z direction in the interlayer dielectric film 25. The contact plug CCw is electrically connected between the electrode film 21 (the word line WL) and the wire 24. The contact plug CCw is provided in a stair portion 2s in which the electrode films 21 are formed in a stepwise pattern at an end of the stack 20, and is electrically connected to the corresponding electrode film 21. The contact plug CCw is provided for transferring a word-line voltage from the CMOS chip 3 to the corresponding electrode film 21. A metal such as copper, tungsten, molybdenum, or titanium nitride (TiN) is used for the contact plug CCw.

The contact plug 29 is provided in the peripheral region of the stack 20 and extends in the Z direction in the interlayer dielectric film 25. The contact plug 29 is provided at least from below the stack 20 to above the stack 20.

The contact plug 29 is electrically connected between the bonding pad 50 and the wire 24. The contact plug 29 is used for supplying a power or a signal from the bonding pad 50 to the array chip 2 or the CMOS chip 3. A metal such as copper, tungsten, molybdenum, or titanium nitride is used for the contact plug 29. The power is a power-supply voltage VDD or a reference voltage VSS lower than the power-supply voltage VDD (e.g., a ground voltage), for example. The signal may be a control signal from outside, or write data or read data.

In the present embodiment, the array chip 2 and the CMOS chip 3 are formed independently of each other and bonded together at the bonding surface B1. Therefore, any CMOS circuit is not provided in the array chip 2. Further, the stack 20 (the memory cell array 2m) is not provided in the CMOS chip 3.

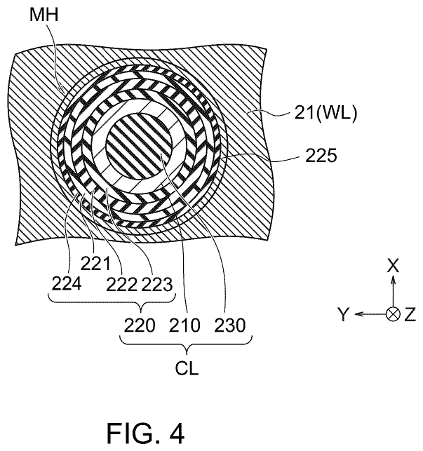

The via 28 and the wires 23 and 24 are provided below the stack 20. The wires 23 and 24 are embedded in the interlayer dielectric film 25. The wire 24 is exposed in the surface of the interlayer dielectric film 25 to be substantially flush therewith. The wires 23 and 24 are electrically connected to, for example, a semiconductor body (210 in FIGS. 3 and 4) of the columnar body CL. A metal such as copper or tungsten is used for the via 28 and the wires 23 and 24. The interlayer dielectric film 25 covers and protects the stack 20, the via 28, and the wires 23 and 24. An insulation film such as a silicon oxide film is used as the interlayer dielectric film 25.

The interlayer dielectric film 25 and the interlayer dielectric film 35 are bonded together at the bonding surface B1, and in association therewith, the wire 24 and the wire 34 are also joined together at the bonding surface B1 to be substantially flush therewith. Accordingly, the array chip 2 and the CMOS chip 3 are electrically connected to each other via the wires 24 and 34.

FIG. 2 is a plan view illustrating an example of the stack 20. The stack 20 includes the stair portion 2s and the memory cell array 2m. The stair portion 2s is provided at an end of the stack 20, for example. The memory cell array 2m is sandwiched between the stair portions 2s or is surrounded by the stair portion 2s. The slits ST are provided from the stair portion 2s at one end of the stack 20 to the stair portion 2s at the other end of the stack 20 through the memory cell array 2m. A slit SHE is provided at least in the memory cell array 2m. The slit SHE is shallower than the slit ST in the Z direction and extends substantially parallel to the slit ST. The slit SHE electrically divides the electrode films 21 in the lower region of the stack 20 for each drain-side selection gate SGD. For example, an insulation film such as a silicon oxide film is used as the slit SHE. Further, the slit ST may include a source wire electrically isolated from the electrode films 21 of the stack 20 and electrically connected to the source layer BSL.

A portion of the stack 20 sandwiched between two of the slits ST illustrated in FIG. 2 is called “block BLK”. The block BLK is the minimum unit for erasing data, for example. The slit SHE is provided in the block BLK. The stack 20 between the slit ST and the slit SHE is called “finger”. The drain-side selection gate SGD is divided for each finger. Therefore, it is possible to place one finger in the block BLK in a selected state by the drain-side selection gate SGD in data writing and data reading. The finger is the minimum unit for data writing and data reading.

FIGS. 3 and 4 are cross-sectional views of an example of a memory cell having a three-dimensional configuration. Each of the columnar bodies CL is provided in a memory hole MH provided in the stack 20. The columnar body CL penetrates through the stack 20 from one end of the stack 20 along the Z direction and is provided in the stack 20 and in the source layer BSL. The columnar body CL includes the semiconductor body 210, a memory film 220, and a core layer 230. The columnar body CL includes the core layer 230 provided at its center, the semiconductor body (semiconductor layer) 210 provided around the core layer 230, and the memory film 220 provided around the semiconductor body 210. The semiconductor body 210 extends in the stack 20 in the Z direction along the memory hole MH and penetrates through the stack 20. The semiconductor body 210 is electrically connected to the source layer BSL. The memory film 220 is provided between the semiconductor body 210 and the electrode film 21 and includes a cover insulation film 221, a charge trapping film 222, and a tunnel insulation film 223. The columnar bodies CL each of which is selected from the corresponding finger are connected to one bit line 23 in common via the vias 28 in FIG. 1. The columnar bodies CL are each provided in a region of the memory cell array 2m, for example.

Further, a block insulation film 224 and a nucleation film 225 are provided between the columnar body CL and the electrode film 21. The block insulation film 224 and the nucleation film 225 cover the electrode film 21 (the word line WL). Accordingly, the block insulation film 224 and the nucleation film 225 are also provided between the electrode film 21 and the insulation film 22. The block insulation film 224 is a film of aluminum oxide containing aluminum and oxygen, for example. The block insulation film 224 prevents back tunneling of electrons from the electrode film 21 toward the memory film 220.

The nucleation film 225 is present at the interface between the block insulation film 224 and the electrode film 21. The nucleation film 225 has a function of promoting growth of molybdenum as the material for the electrode film 21. More detailed configurations of the nucleation film 225 are described later by way of FIG. 5.

As illustrated in FIG. 4, the shape of the memory hole MH in the X-Y plane is circular or elliptical, for example. In association with this shape, the shape of the columnar body CL in the X-Y plane is also circular or elliptical, for example.

The semiconductor body 210 has the shape of a cylinder with a bottom, for example. Polysilicon is used for the semiconductor body 210, for example. The material for the semiconductor body 210 is undoped silicon, for example. The semiconductor body 210 may be made of p-type silicon. The semiconductor body 210 serves as a channel of each of a drain-side selection transistor, the memory cell MC, and a source-side selection transistor. That is, the memory cells MC each include a storage region between the semiconductor body 210 and the electrode film 21 serving as the word line WL, and are stacked in the Z direction. One ends of the semiconductor bodies 210 in the same memory cell array 2m are electrically connected to the source layer BSL in common.

As illustrated in FIG. 3, the memory film 220 includes the cover insulation film 221, the charge trapping film 222, the tunnel insulation film 223, the block insulation film 224, and the nucleation film 225, for example. A portion of the memory film 220 other than the nucleation film 225 and the block insulation film 224 is provided between the inner wall of the memory hole MH (the stack 20) and the semiconductor body 210, as a portion of the columnar body CL. The shapes of the cover insulation film 221, the charge trapping film 222, and the tunnel insulation film 223 are cylindrical, for example. The cover insulation film 221, the charge trapping film 222, and the tunnel insulation film 223 extend in the Z direction.

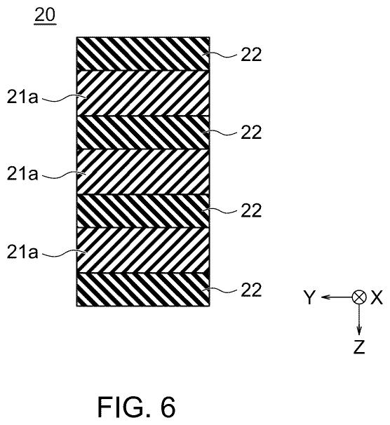

The cover insulation film 221 is located between the semiconductor body 210 and the stack 20. In more detail, the cover insulation film 221 is provided between the insulation film 22 and the charge trapping film 222 and between the block insulation film 224 (or the nucleation film 225) and the charge trapping film 222. The cover insulation film 221 contains silicon oxide, for example. The cover insulation film 221 protects the charge trapping film 222 from being etched when sacrifice films (21a in FIG. 6) are replaced with the electrode films 21 (in a replacement process).

The charge trapping film 222 is provided between the cover insulation film 221 and the semiconductor body 210, in more detail, between the cover insulation film 221 and the tunnel insulation film 223. The charge trapping film 222 contains silicon nitride or silicon oxynitride, for example, and has trap sites trapping electric charges therein. A portion of the charge trapping film 222, sandwiched between the electrode film 21 serving as the word line WL and the semiconductor body 210, constitutes a storage region of the memory cell MC as a charge trapping portion. The threshold voltage of the memory cell MC changes depending on whether electric charges are present in the charge trapping portion or in accordance with the amount of electric charges trapped in the charge trapping portion. accordingly, the memory cell MC retains information.

The tunnel insulation film 223 is provided between the semiconductor body 210 and the charge trapping film 222. The tunnel insulation film 223 contains silicon oxide, or silicon oxide and silicon nitride, for example. The tunnel insulation film 223 is a potential barrier between the semiconductor body 210 and the charge trapping film 222. For example, electrons and holes pass (tunnel) through the potential barrier by the tunnel insulation film 223, when electrons are injected from the semiconductor body 210 to the charge trapping film 222 (a write operation) and when holes are injected from the semiconductor body 210 to the charge trapping film 222 (an erase operation), respectively.

The core layer 230 is embedded in a space within the cylindrical semiconductor body 210. The shape of the core layer 230 is columnar, for example. For example, the core layer 230 contains silicon oxide and is insulating.

FIG. 5 is a cross-sectional view illustrating a portion of the memory cell in FIG. 3 in more detail. In the columnar body CL in the memory hole MH, the charge trapping film 222 and the cover insulation film 221 are illustrated. The block insulation film (e.g., an aluminum oxide film) 224 is provided between the cover insulation film 221 of the columnar body CL and the electrode film 21 and between the insulation film 22 and the electrode film 21. The nucleation film 225 is present at the interface between the block insulation film 224 and the electrode film 21. The nucleation film 225 is provided in order to promote growth of molybdenum as the material for the electrode film 21 and contains the same material as a main component of the electrode film 21, that is, molybdenum as a main component.

Here, the configuration of the nucleation film 225 is described.

The nucleation film 225 is present at the interface between the block insulation film 224 and the electrode film 21. The nucleation film 225 contains molybdenum as its main component. The nucleation film 225 is a conductive film in which a first material is contained in molybdenum. The concentration of the first material in the nucleation film 225 is higher than the oxygen concentration in the nucleation film 225. The first material is at least one of carbon (C), silicon (Si), and boron (B), for example. The first material may be a combination of two or more of carbon (C), silicon (Si), and boron (B). For the nucleation film 225, molybdenum containing carbon (e.g., MoC), molybdenum containing silicon (e.g., MoSi), or molybdenum containing boron (e.g., MoB) or a combination thereof is used, for example. Further, a molecular structure containing nitrogen may be used for the intermediate film 225, for example. The oxygen content of the nucleation film 225 is 1 at % or less or 10²¹ atoms/cm⁻³ or less.

In a case of using molybdenum nitride (MoN) for the nucleation film 225, molybdenum bonds to oxygen more easily than to nitrogen and, consequently, is stabilized as MoON containing a large amount of oxygen. For example, in a case of depositing molybdenum nitride, MoO₂Cl₂ is used as a material gas, and ammonia (NH₃) is used as a reducing gas. MoO₂Cl₂ is reduced with ammonia to produce MoON and ClH. Since molybdenum is more stable in bonding with oxygen than with nitrogen, it is difficult to release oxygen from molybdenum oxynitride (MoON) to 1 at % or less or 10²¹ atoms/cm⁻³ or less. That is, it is actually difficult to deposit molybdenum nitride (MoN) with an oxygen content of 1 at % or less or 10²¹ atoms/cm⁻³ or less.

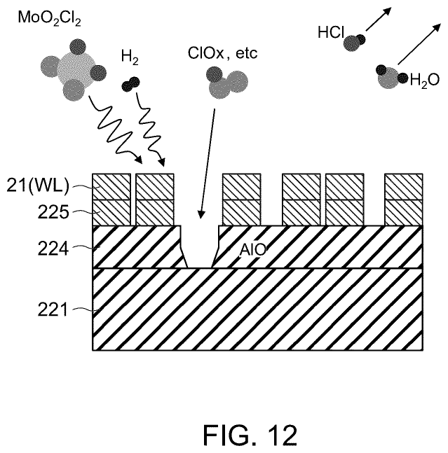

Further, in a case of using molybdenum nitride for the nucleation film 225, there is a problem that molybdenum nitride causes deterioration of the erase saturation characteristics and the HTDR characteristics of memory cells. Regarding the erase saturation characteristics, the higher the oxygen concentration in molybdenum nitride of the nucleation film 225 is, the more molybdenum atoms from the nucleation film 225 diffuse in the block insulation film 224. The molybdenum atoms are substituted for sites where aluminum atoms are present in the aluminum oxide film as the block insulation film 224. Meanwhile, aluminum atoms diffuse from the block insulation film 224 and are substituted for molybdenum atoms in the nucleation film 225 or the electrode film 21. As a result, the insulating property of the block insulation film 224 deteriorates, the number of back tunneling electrons injected from the electrode film 21 into the charge trapping film 222 increases, and the erase saturation characteristics deteriorate. There is a tendency that, with increase in the oxygen concentration in the molybdenum nitride film as the nucleation film 225 and decrease in the nitrogen concentration therein, the film continuity of the molybdenum nitride film itself deteriorates. When the distance between breaks in the nucleation film 225 becomes wider, the block insulation film 224 is exposed from the nucleation film 225 as illustrated in FIG. 12, and the block insulation film 224 is etched by a chlorine component (e.g., ClOx, where x is a positive number) during formation of the electrode film 21. In this case, the block insulation film 224 is also broken, so that memory cells at this position become dysfunctional. Hence, the yield of the entire wafer is worsened. It is therefore preferable that the oxygen content of the nucleation film 225 is as low as possible, although that oxygen content cannot be made zero. For example, that oxygen content is preferably 1 at % or less or 10²¹ atoms/cm⁻³ or less.

Accordingly, in the present embodiment, carbon-containing molybdenum (e.g., MoC) is used as the nucleation film 225, for example. For carbon-containing molybdenum, MoO₂Cl₂ is used as the deposition material gas, and C₂H₂ is used as the reducing gas. Accordingly, carbon-containing molybdenum (MoC), carbon oxide (COx), and hydrogen chloride (ClH) are produced. Oxygen of the deposition material gas MoO₂Cl₂ is released as carbon oxide. Accordingly, carbon-containing molybdenum deposited by ALD (Atomic Layer Deposition) can have an oxygen concentration reduced to 1 at % or less (e.g., 1×10¹⁸ cm⁻³ to 10²⁰ cm⁻³). Accordingly, it is possible to prevent the nucleation film 225 from being broken. Consequently, the nucleation film 225 becomes closer to a continuous film, and therefore can promote growth of the electrode film 21 and prevent the block insulation film 224 from being etched unintentionally. Further, the nucleation film 225 can prevent deterioration of the erase saturation characteristics and the HTDR characteristics. Furthermore, since carbon-containing molybdenum is lower than MoN and MoON in resistivity, the entire resistance of the nucleation film 225 and the electrode film 21 (the word line WL) can be lowered.

Alternatively, molybdenum containing nitrogen and carbon (e.g., MoCN) may be used as the nucleation film 225, for example. In a case where the nucleation film 225 contains nitrogen, although the resistivity of the nucleation film 225 increases to some extent, the nucleation film is not broken, and deterioration of the erase saturation characteristics and the HTDR characteristics is prevented, unlike a nucleation film containing oxygen. Therefore, as compared with oxygen-containing molybdenum, molybdenum containing nitrogen and carbon (e.g., MoCN) is more preferable as the nucleation film 225.

Alternatively, silicon-containing molybdenum (e.g., MoSi) may be used as the nucleation film 225, for example. For silicon-containing molybdenum, MoO₂Cl₂ is used as the deposition material gas, and SiH₄ or Si₂H₅ is used as the reducing gas. As a silicon additive gas, SiH₂Cl₂, SiHCl₃, SiCl₄, Si₂Cl₆, or the like may be added. In this manner, silicon-containing molybdenum (MoSi) and hydrogen chloride (ClH) are produced. Oxygen of the deposition material gas MoO₂Cl₂ is released as H₂O. Accordingly, silicon-containing molybdenum deposited by ALD can have an oxygen concentration reduced to 1 at % or less (e.g., 1×10¹⁸ cm⁻³ to 10²⁰ cm⁻³). Therefore, it is possible to prevent the nucleation film 225 from being broken. Consequently, the nucleation film 225 becomes closer to a continuous film, and therefore can promote growth of the electrode film 21 and prevent the block insulation film 224 from being etched unintentionally. Further, the nucleation film 225 can prevent deterioration of the erase saturation characteristics and the HTDR characteristics. Furthermore, silicon-containing molybdenum is lower than MoN and MoON in resistivity. Therefore, the entire resistance of the nucleation film 225 and the electrode film 21 (the word line WL) can be lowered. Nitrogen or carbon may be contained in silicon-containing molybdenum.

Alternatively, boron-containing molybdenum (e.g., MoB) is used as the nucleation film 225, for example. For boron-containing molybdenum, MoO₂Cl₂ is used as the deposition material gas, and B₂H₄ is used as the reducing gas. As a boron additive gas, BCl₃ may be used. In this manner, boron-containing molybdenum (MoB), boron oxide (BOx), and hydrogen chloride (ClH) are produced. Oxygen of the deposition material gas MoO₂Cl₂ is released as H₂O. Accordingly, boron-containing molybdenum deposited by ALD can have an oxygen concentration reduced to 1 at % or less (e.g., 1×10¹⁸ cm⁻³ to 10²⁰ cm⁻³). Therefore, it is possible to prevent the nucleation film 225 from being broken. Consequently, the nucleation film 225 becomes closer to a continuous film, and therefore can promote growth of the electrode film 21 and prevent the block insulation film 224 from being etched unintentionally. Further, the nucleation film 225 can prevent deterioration of the erase saturation characteristics and the HTDR characteristics. Furthermore, boron-containing molybdenum is lower than MoN and MoON in resistivity. Therefore, the entire resistance of the nucleation film 225 and the electrode film 21 (the word line WL) can be lowered. Nitrogen, carbon or silicon may be contained in silicon-containing molybdenum.

As described above, since the nucleation film 225 according to the present embodiment is made of molybdenum containing at least one of carbon (C), silicon (Si), and boron (B), the oxygen concentration is reduced to 1 at % or less (e.g., 1×10¹⁸ cm⁻³ to 10²⁰ cm⁻³). Accordingly, the nucleation film 225 is not broken, and can promote growth of the electrode film 21, so that it is possible to improve the high temperature data retention characteristics (HTDR characteristics) and the erase saturation characteristics of the memory cell MC. Further, production of molybdenum oxide that has high resistance is reduced in the nucleation film 225. Therefore, the resistance of the electrode film 21 can be suppressed to be low.

Next, a manufacturing method of the semiconductor storage device 1 is described.

FIGS. 6 to 10 are cross-sectional views illustrating an example of a manufacturing method of the semiconductor storage device 1 according to the present embodiment.

First, as illustrated in FIG. 6, the stack 20 of the array chip 2 is formed by alternately stacking the material films 21a as the sacrifice films and the insulation films 22 in the −Z direction one layer at a time. A silicon nitride film is used as the material film 21a, for example. A silicon oxide film is used as the insulation film 22, for example.

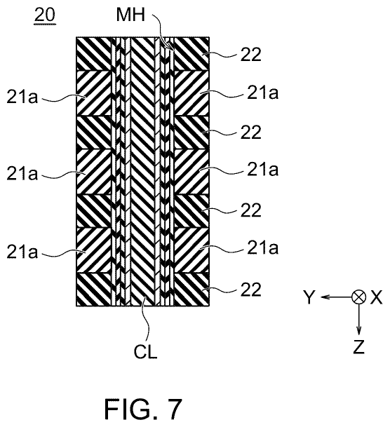

Next, the memory holes MH penetrating through the stack 20 in the Z direction are formed by lithography and etching. Next, as illustrated in FIG. 7, the columnar bodies CL are formed in the memory holes MH, respectively. The columnar bodies CL are formed by depositing the cover insulation film 221, the charge trapping film 222, the tunnel insulation film 223, and the semiconductor body 210 illustrated in FIGS. 3 and 4 on the sidewalls of the memory holes MH.

Next, the slit ST illustrated in FIG. 2 is formed in the stack 20 by lithography and etching. The slit ST is provided to penetrate through the stack 20 in the Z direction.

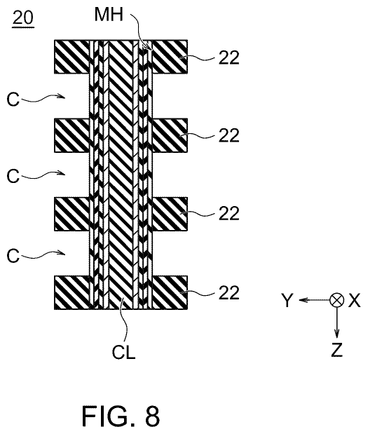

Next, the material films 21a are removed via the slit ST by wet etching. With this process, as illustrated in FIG. 8, a space C is formed between the insulation films 22 adjacent to each other in the Z direction (in a portion where each material film 21a has been present).

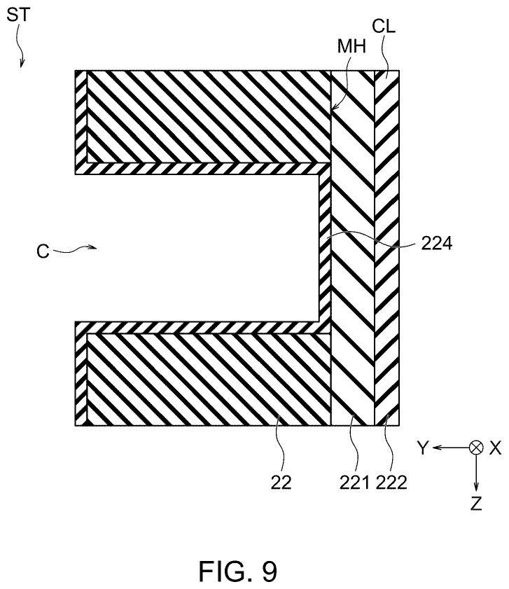

FIGS. 9 to 11 illustrate an enlarged cross-section of a portion including the space C.

Next, as illustrated in FIG. 9, an aluminum oxide film as the block insulation film 224 is deposited by ALD on the inner walls of the space C and the slit ST via the slit ST.

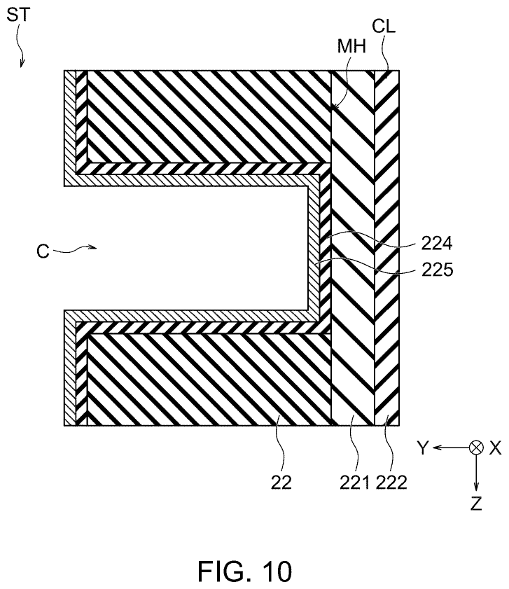

Next, as illustrated in FIG. 10, the nucleation film 225 is deposited by ALD on the block insulation film 224 on the inner walls of the space C and the slit ST via the slit ST.

In a case where the nucleation film 225 is made of molybdenum containing carbon (MoC), MoO₂Cl₂ is used as the material gas, and C₂H₂ is used as the reducing gas. For example, the material gas MoO₂Cl₂ and the reducing gas C₂H₂ are alternately supplied, and carbon-containing molybdenum is formed as the nucleation film 225. The deposition temperature is 400° C. to 600° C., for example. The carbon addition concentration in molybdenum of the nucleation film 225 is 1 at % to 50 at %, for example.

At this time, since oxygen bonds more easily to carbon than to molybdenum, oxygen is released as CO₂, for example. Thus, as the nucleation film 225, carbon-containing molybdenum with an oxygen concentration reduced to 1 at % or less (e.g., 1×10¹⁸ cm⁻³ to 10²⁰ cm⁻³) can be obtained.

In a case where the nucleation film 225 is molybdenum containing nitrogen and carbon (MoCN), it suffices to add carbon after nitrogen-containing molybdenum (MoN) is formed. For example, the material gas MoO₂Cl₂ and the reducing gas NH₃ are alternately supplied to form nitrogen-containing molybdenum, and thereafter nitrogen-containing molybdenum is annealed in an atmosphere of carbon, such as C₂H₂. With this process, molybdenum containing nitrogen and carbon (MoCN) is formed.

In a case where the nucleation film 225 is molybdenum containing silicon (MoSi), MoO₂Cl₂ is used as the material gas, and SiH₄ or Si₂H₅ is used as the reducing gas. Further, SiH₂Cl₂, SiHCl₃, SiCl₄, Si₂Cl₆, or the like may be added as a silicon additive gas. For example, in a case of using silane (SiH₄) as the reducing gas, the material gas MoO₂Cl₂ and silane as the reducing gas are alternately supplied, and silicon-containing molybdenum is formed as the nucleation film 225. The deposition temperature is 350° C. to 550° C., for example. The silicon addition concentration with respect to molybdenum is 1 at % to 33 at %, for example.

Since the reducing gas (SiH₄ or Si₂H₅) described above has a higher reducing power than H₂ conventionally used as the reducing gas, the reducing gas described above can efficiently remove oxygen from MoO₂Cl₂. Thus, as the nucleation film 225, silicon-containing molybdenum with an oxygen concentration reduced to 1 at % or less (e.g., 1×10¹⁸ cm⁻³ to 10²⁰ cm⁻³) can be obtained. Prior to deposition of silicon-containing molybdenum, a thin film of titanium (Ti) or titanium nitride (TiN) may be formed as a base material on the surface of the block insulation film 224. In this case, titanium may be contained in silicon-containing molybdenum, for example, at a concentration of 10 at % or less.

In a case where the nucleation film 225 is molybdenum containing boron (MoB), MoO₂Cl₂ is used as the material gas, and B₂H₄ is used as the reducing gas. As a boron additive gas, BCl₃ may be used. For example, in a case of using diborane (B₂H₄ or B₂H₆) as the reducing gas, the material gas MoO₂Cl₂ and diborane as the reducing gas are alternately supplied, and boron-containing molybdenum is formed as the nucleation film 225.

Since the reducing gas (B₂H₄) described above has a higher reducing power than H₂ conventionally used as the reducing gas, the reducing gas described above can efficiently remove oxygen from MoO₂Cl₂. Thus, as the nucleation film 225, boron-containing molybdenum with an oxygen concentration reduced to 1 at % or less (e.g., 1×10¹⁸ cm⁻³ to 10²⁰ cm⁻³) can be obtained.

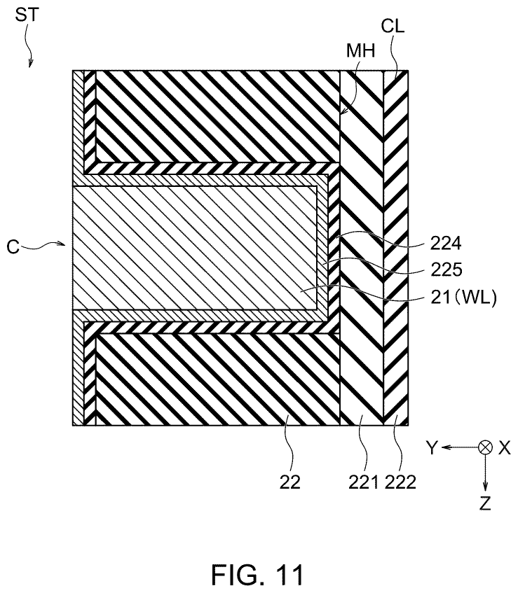

Next, as illustrated in FIG. 11, molybdenum is deposited on the inner wall of the space C as the material for the electrode film 21. At this time, molybdenum grows by using the nucleation film 225 as a nucleus and can easily be deposited in the space C isotropically. The impurity concentration in the electrode film 21 that has grown by using the nucleation film 225 as the nucleus is lower than the impurity concentration (first material concentration) in the nucleation film 225. Therefore, the resistivity of the electrode film 21 is smaller than that of the nucleation film 225. Hence, the entire resistance of the nucleation film 225 and the electrode film 21 becomes lower.

As illustrated in FIG. 12, in a case where the nucleation film 225 contains a large amount of oxygen, the nucleation film 225 is broken. FIG. 12 is a conceptual diagram illustrating a process of depositing the electrode film 21 on the broken nucleation film 225. In this case, the material gas MoO₂Cl₂ for the electrode film 21 and hydrogen (H₂) as the reducing gas produce a chlorine compound (e.g., ClOx), HCl, and H₂O. The chlorine compound etches the block insulation film 224 through a gap in the broken nucleation film 225. Consequently, the block insulation film 224 is also broken, so that memory cells become dysfunctional.

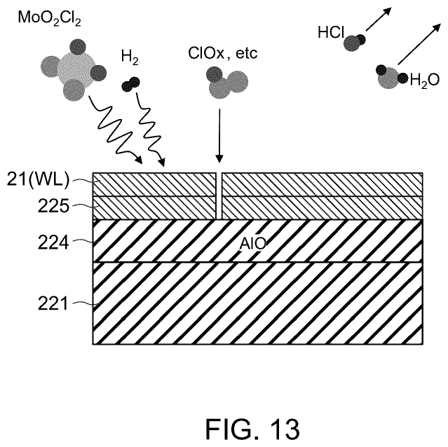

Meanwhile, as illustrated in FIG. 13, in a case where the nucleation film 225 contains oxygen at a concentration of 1 at % or less (e.g., 1×10¹⁸ cm⁻³ to 10²⁰ cm⁻³), the nucleation film 225 is continuous or the gap between the breaks becomes narrow. FIG. 13 is a conceptual diagram illustrating a process of depositing the electrode film 21 on the nucleation film 225 according to the present embodiment. In this case, the chlorine compound (e.g., ClOx) produced in the process of depositing the electrode film 21 does not reach the block insulation film 224. Consequently, the continuity of the block insulation film 224 is maintained, so that the function of memory cells can be maintained.

Next, while the electrode film 21 and the nucleation film 225 in the space C illustrated in FIG. 11 are left, the materials for the electrode film 21 and the nucleation film 225 on the inner wall of the slit ST are removed.

Thereafter, an insulation film (not illustrated) is formed in the slit ST, and further the slit ST is embedded with an insulating material or a conductive material. Furthermore, a contact, a multilayer wiring layer, and the like (not illustrated) are formed. The semiconductor storage device 1 according to the present embodiment is completed in this manner.

As described above, according to the present embodiment, molybdenum containing at least one of carbon (C), silicon (Si), and boron (B) is formed as the nucleation film 225. Thus, the oxygen concentration in the nucleation film 225 can be reduced to 1 at % or less (e.g., 1×10¹⁸ cm⁻³ to 10²⁰ cm⁻³). As a result, while the nucleation film 225 is prevented from being broken and the block insulation film 224 is protected, the high temperature data retention characteristics (HTDR characteristics) and the erase saturation characteristics of the memory cell MC can be improved.

The HTDR characteristics indicate that the amount of a change in a data retention state of the memory cell MC retaining data (the shift amount of the threshold voltage) before and after heating of that memory cell MC. The smaller the shift amount of the threshold voltage is, the better the high temperature data retention characteristics are.

Erase saturation is a state where the threshold voltage of the memory cell MC when data has been erased becomes the minimum. When a negative voltage applied to the word line WL (the electrode film 21) is made higher on the negative side, holes injected into the charge trapping film 222 increase, and the amount of neutralization with electrons increases. Therefore, the threshold voltage of the memory cell MC decreases. However, when all the electrons in the charge trapping film 222 are eliminated, the threshold voltage of the memory cell MC does not decrease any more. This minimum value of the threshold voltage of the memory cell MC is erase saturation. Since the operation of the memory cell becomes difficult when the erase saturation characteristics are insufficient, it is understood that it is desirable to prevent deterioration of the erase saturation characteristics.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a stack of a plurality of electrode films and a plurality of first insulation films alternately stacked one layer at a time in a first direction;
a columnar body including a semiconductor layer provided to penetrate through the stack in the first direction;
a second insulation film provided between the columnar body and each of the electrode films; and
a conductive film provided between each of the electrode films and the second insulation film and containing molybdenum (Mo) containing a first material whose concentration is higher than an oxygen concentration.

2. The device of claim 1, wherein the first material is at least one of carbon (C), silicon (Si), and boron (B).

3. The device of claim 1, wherein an oxygen content of the conductive film is 1 at % or less or 10²¹ atoms/cm⁻³ or less.

4. The device of claim 1, wherein the conductive film is a nucleation film used for causing the electrode films to grow.

5. The device of claim 1, wherein the electrode films contain molybdenum as a main component thereof.

6. The device of claim 1, wherein the conductive film contains molybdenum as a main component thereof.

7. The device of claim 1, wherein a resistivity of the conductive film is smaller than a resistivity of molybdenum containing nitrogen (MoN).

8. The device of claim 1, wherein a resistivity of each of the electrode films is smaller than a resistivity of the conductive film.

9. The device of claim 1, wherein the columnar body includes
a third insulation film provided between the semiconductor layer and the second insulation film,
a fourth insulation film provided between the third insulation film and the semiconductor layer, and
a fifth insulation film provided between the fourth insulation film and the semiconductor layer.

10. A manufacturing method of a semiconductor storage device, comprising:
alternately stacking a plurality of material films and a plurality of first insulation films one layer at a time in a first direction to form a stack;
forming a columnar body penetrating through the stack in the first direction;
removing the material films to form a space between the first insulation films; and
forming a conductive film on an inner wall of the space, where the conductive film containing molybdenum (Mo) containing a first material whose concentration is higher than an oxygen concentration; and
forming a plurality of electrode films inside the conductive film in the space.

11. The method of claim 10, wherein the first material is at least one of carbon (C), silicon (Si), and boron (B).

12. The method of claim 10, wherein an oxygen content of the conductive film is 1 at % or less or 10²¹ atoms/cm⁻³ or less.

13. The method of claim 10, wherein the conductive film is used as a nucleation film causing the electrode films to grow.

14. The method of claim 10, wherein the electrode films contain molybdenum as a main component thereof.

15. The method of claim 10, wherein the conductive film contains molybdenum as a main component thereof.

16. The method of claim 10, wherein a resistivity of the conductive film i smaller than a resistivity of molybdenum containing nitrogen (MoN).

17. The method of claim 10, wherein a resistivity of each of the electrode films is smaller than a resistivity of the conductive film.
